(19) United States
(12) Patent Application Publication
(10) Pub. No.: US 2026/0024979 A1
(43) Pub. Date: Jan. 22, 2026

(54) BUSBARS FOR A POWER DISTRIBUTION UNIT

(71) Applicant: Eaton Intelligent Power Limited, Dublin 4 (IE)

(72) Inventors: Ankitkumar Chauhan, Mahesana (IN); Deepak Patidar, Pratapgarh (IN); Vidula Athawale, Thane (IN)

(21) Appl. No.: 19/270,092

(22) Filed: Jul. 15, 2025

Related U.S. Application Data
(60) Provisional application No. 63/672,025, filed on Jul. 16, 2024.

(51) Int. Cl. H02G 5/10; H05K 7/20

(52) U.S. Cl. CPC H02G 5/10; H05K 7/20936

(57) ABSTRACT

In some aspects, the techniques described herein relate to a busbar for electrically connecting components in a power distribution unit (PDU), the busbar including: a first metallic bar configured at one end to be coupled to a terminal of the PDU; and a heat distribution block at the one end of the first metallic bar. In some aspects, the techniques described herein relate to a busbar, wherein the heat distribution block includes a vapor chamber. In some aspects, the techniques described herein relate to a busbar, wherein a shape of the vapor chamber conforms to a shape of the one end. In some aspects, the techniques described herein relate to a busbar, wherein the heat distribution block includes a metal block, wherein the metal block includes a phase change material.

### BACKGROUND

Power distribution units (PDUs), and more particularly, battery disconnect units (BDU), are vital components in vehicles. These units need to be safeguarded from high temperatures because they are subjected to high surge in currents. The introduction of high current or surges can cause PDUs in a vehicle to overheat. Therefore, mitigating temperature spikes caused by high current surges in PDUs and BDUs is ideal.

### BRIEF SUMMARY

Busbars for dispersing heat and mitigating temperature in power distribution units are described. Advantageously, the described busbars can reduce temperature difference at terminals of a power distribution unit (PDU) to prevent problems caused by high current surges. The described busbars can improve the functioning and lifespan of a PDU by mitigating temperature spikes by acting as a heat spreader and by increasing current carrying capacity.

In some aspects, the techniques described herein relate to a busbar for electrically connecting components in a power distribution unit (PDU), the busbar including: a first metallic bar configured at one end to be coupled to a terminal of the PDU; and a heat distribution block at the one end of the first metallic bar. In some aspects, the techniques described herein relate to a busbar, wherein the heat distribution block includes a vapor chamber. In some aspects, the techniques described herein relate to a busbar, wherein a shape of the vapor chamber conforms to a shape of the one end. In some aspects, the techniques described herein relate to a busbar, wherein the heat distribution block includes a metal block, wherein the metal block includes a phase change material.

In some aspects, the techniques described herein relate to a power distribution unit (PDU), including: a first terminal; and a busbar, wherein the busbar includes: a first metallic bar having one end coupled to the first terminal of the PDU; and a heat distribution block at the one end of the first metallic bar. In some aspects, the techniques described herein relate to a PDU, wherein the PDU includes a battery disconnect unit. In some aspects, the techniques described herein relate to a busbar, wherein the heat distribution block includes a vapor chamber. In some aspects, the techniques described herein relate to a busbar, wherein the heat distribution block includes a metal block, wherein the metal block includes a phase change material.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example embodiment of plurality of busbars coupled to a power distribution unit (PDU).

FIG. 2A illustrates an example embodiment of a one-sided vapor chamber busbar.

FIG. 2B illustrates an example embodiment of a two-sided vapor chamber busbar.

FIG. 3A illustrates an example embodiment of a one-sided vapor chamber busbar.

FIG. 3B illustrates an example embodiment of a two-sided vapor chamber busbar.

FIG. 3C illustrates an example embodiment of plurality of busbars coupled to a power distribution unit (PDU).

FIGS. 4A-4B illustrate example embodiments of a phase change material (PCM) busbar. FIG. 4C illustrates an example PCM slab.

FIG. 5A illustrates a graph illustrating effects of vapor chamber busbar with one-sided architecture.

FIG. 5B illustrates a temperature map of terminals of a PDU coupled by a contact bridge using conventional busbars. FIG. 5C illustrates a temperature map of terminals of a PDU coupled by a contact bridge using a vapor chamber busbar with one-sided architecture.

### DETAILED DESCRIPTION

Busbars for dispersing heat and mitigating temperature in power distribution units (PDUs) are described. Advantageously, the described busbars can reduce temperature difference at terminals of a PDU to prevent problems caused by high current surges. The described busbars can improve the functioning and lifespan of a PDU by mitigating temperature spikes by acting as a heat spreader and by increasing current carrying capacity.

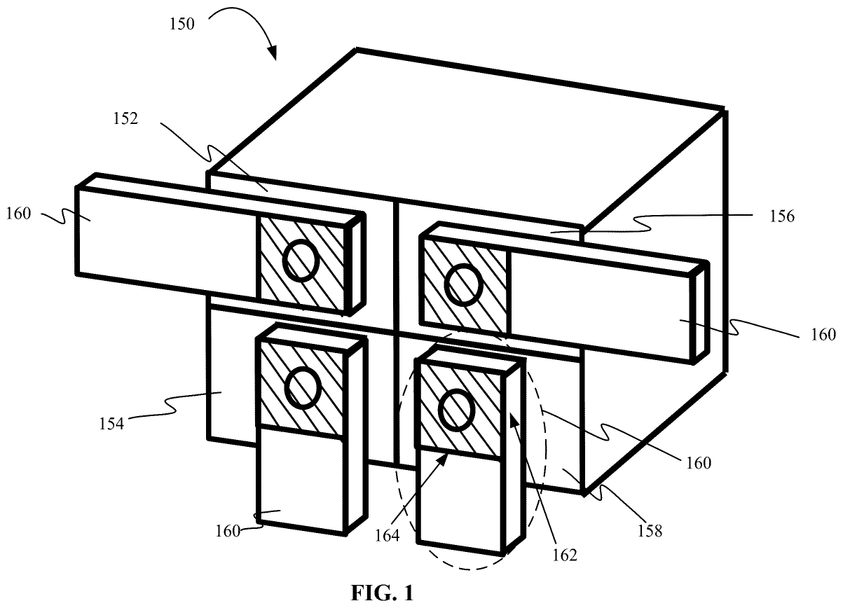

FIG. 1 illustrates an example embodiment of plurality of busbars coupled to a power distribution unit (PDU). Referring to FIG. 1, PDU 150 includes a first terminal 152, a second terminal 154, a third terminal 156, and a fourth terminal 158. A plurality of busbars 160 can be coupled to the terminals of the PDU 150.

In some cases, the PDU 150 is a PDU in a vehicle. Example PDUs 150 can include, but are not limited to, a battery, a battery disconnect unit (BDU), a generator, an inverter, a converter, and a capacitor. In some cases, the PDU 150 provides for protection of the electrical system, including fusing and/or connection or disconnection of an electrical system (e.g., a vehicle) or individual aspects of the electrical systems. The first terminal 152 can be coupled to the third terminal 156 by a contact bridge (not shown) within the body of the PDU 150.

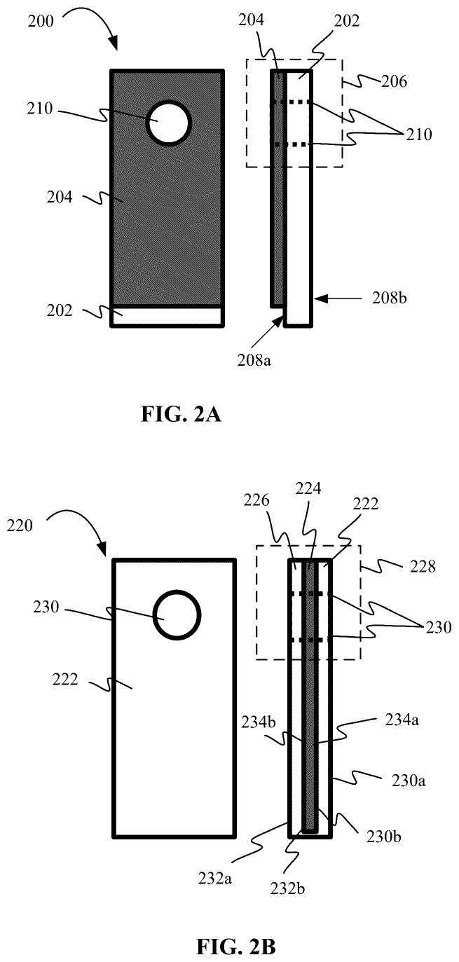

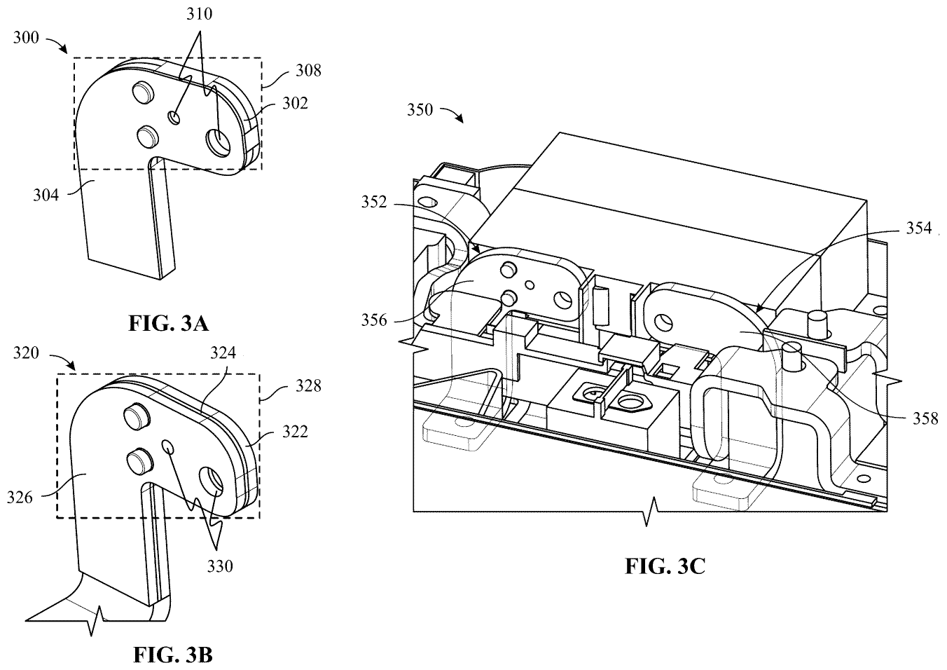

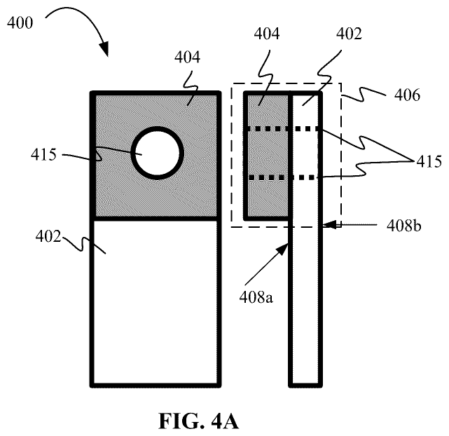

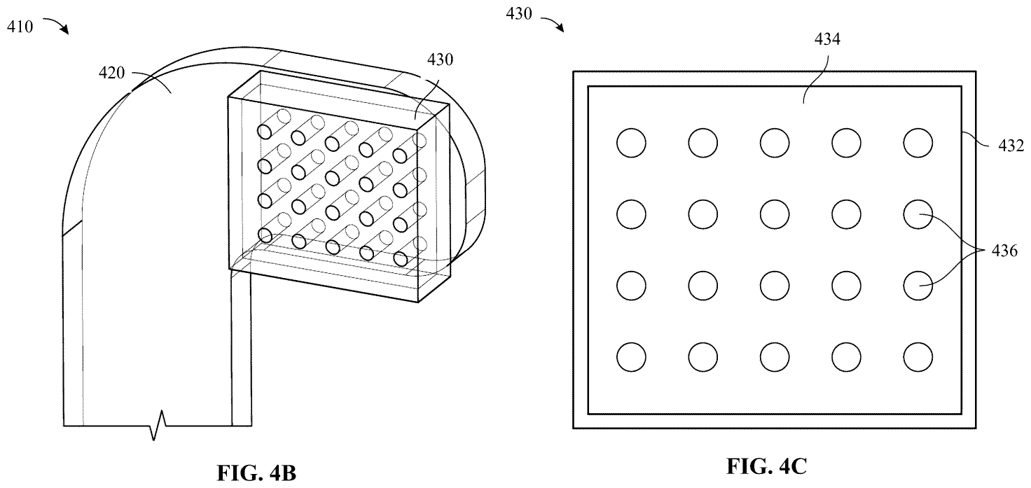

Each of the plurality of busbars 160 can include a first metallic bar 162 configured at one end to be coupled to a terminal of the PDU (e.g., fourth terminal 158) and a heat distribution block 164 at the one end of the first metallic bar. The heat distribution block can conform to a shape of the one end. In some cases, the heat distribution block 164 can be embodied as a vapor chamber, as described with respect to FIGS. 2A-2B and FIGS. 3A-3B. In some cases, the heat distribution block 164 can be embodied as a metal block, wherein the metal block includes a phase change material, for example, as described with respect to FIGS. 4A-4C.

The plurality of busbars 160 can be coupled to a terminal of the PDU 150 (e.g., first terminal 152, second terminal 154, third terminal 156, and fourth terminal 158) to distribute high current power at the PDU 150. Each of the plurality of busbars 160 can be an electrical connection point that gathers electric power from an incoming power line through which electricity is passed in a PDU and then disperses the electrical power to an outgoing power line. The plurality of busbars 160 transport and distribute electricity to enhance the efficiency of the systems.

FIG. 2A illustrates an example embodiment of a one-sided vapor chamber busbar. Referring to FIG. 2A, a one-sided vapor chamber busbar 200 can include a metallic bar 202 and a vapor chamber 204. The vapor chamber 204 is a thin vacuum-sealed metal enclosure/envelope that includes a liquid and an internal wick structure (e.g., microstructures).

The metallic bar 202 can be configured at one end to be coupled to a terminal of a PDU (e.g., terminal contact portion 206). The vapor chamber 204 can conform to a shape of the one end. The vapor chamber 204 can be at the terminal contact portion 206 of the metallic bar 202. In some cases, the vapor chamber 204 can be close to the terminal contact portion 206 of the busbar 200. In some cases, the vapor chamber 204 can extend a distance down a length of the one-sided vapor chamber busbar 200. The one-sided vapor chamber busbar 200 can include a hole 210 extending through the one-sided vapor chamber busbar 200 (e.g., including a hole formed in the vapor chamber 204 and a corresponding hole formed in the metallic bar 202).

Advantageously, the vapor chamber 204 can decrease the temperature differential between a terminal contact portion 206 of the one-sided vapor chamber busbar 200 and an end portion on the opposite side of the one-sided vapor chamber busbar 200. The vapor chamber 204 can spread heat in two dimensions. The liquid within the vapor chamber 204 evaporates and condenses to efficiently transfer heat. In some cases, the vapor chamber 204 has a thickness selected from a range of 0.5 mm-5 mm.

The metallic bar 202 can be formed of any suitable metal, including, but not limited to, copper, brass, and aluminum. In some cases, the metallic bar 202 can have a thickness selected from a range of 1 mm to 10 mm. In some cases, the metallic bar 202 has a thickness of 3 mm.

The vapor chamber 204 can be coupled to the metallic bar 202. The metallic bar 202 can include a first side 208a coupled to the vapor chamber 204 and a second side 208b configured to be coupled to a terminal of a PDU (e.g., the first terminal 152, the second terminal 154, the third terminal 156, or the fourth terminal 158 of PDU 150 as described with respect to FIG. 1). The one-sided vapor chamber busbar 200 can include a terminal contact portion 206 at the one end of the one-sided vapor chamber busbar 200 configured to be coupled to a terminal of a PDU.

The one-sided vapor chamber busbar 200 can be a variety of shapes/sizes suitable for coupling to a terminal of PDU. Example shapes for the one-sided vapor chamber busbar 200 include a flat strip, a solid bar, and a rod. In some cases, the one-sided vapor chamber busbar 200 is curved, such that the terminal contact portion 206 is offset from an extending portion of the one-sided vapor chamber busbar 200. The metallic bar 202 can be formed of any suitable metal, including, but not limited to, copper, brass, and aluminum. In some cases, the shape of the vapor chamber 204 corresponds to the shape of the metallic bar 202.

FIG. 2B illustrates an example embodiment of a two-sided vapor chamber busbar. Referring to FIG. 2B, a two-sided vapor chamber busbar 220. The two-sided vapor chamber busbar 220 can include a first metallic bar 222 configured at one end (e.g., terminal contact portion 228) to be coupled to a terminal of a PDU (e.g., the first terminal 152, the second terminal 154, the third terminal 156, or the fourth terminal 158 of PDU 150 as described with respect to FIG. 1), a vapor chamber 224, and a second metallic bar 226 coupled to the first metallic bar 222 with the vapor chamber 224 there between. In some cases, the second metallic bar 226 can contact the first metallic bar 222 toward an opposite end to the one end having the vapor chamber (e.g., the terminal contact portion 228). The two-sided vapor chamber busbar 220 can include a hole 230 extending through the two-sided vapor chamber busbar 220 (e.g., including a hole formed in the vapor chamber 224, a corresponding hole formed in the first metallic bar 222, and a corresponding hole formed in the second metallic bar 226).

The vapor chamber 224 of the two-sided vapor chamber busbar 220 can be coupled to both the first metallic bar 222 and the second metallic bar 226. The first metallic bar 222 can include a first side 230a configured to be coupled to a terminal of a PDU and a second side 230b coupled to a first side 234a the vapor chamber 224. The second metallic bar 226 can include a first side 232a and a second side 232b coupled to a second side 234b of the vapor chamber 224. The two-sided vapor chamber busbar 220 can include a terminal contact portion 228 at an end of the two-sided vapor chamber busbar 220 configured to be coupled to a terminal of a PDU.

In some cases, the first metallic bar 222 is coupled to the second metallic bar 226. In some cases, a bottom end of the first metallic bar 222 is coupled to a bottom end of the second metallic bar 226. In some cases, the first metallic bar 222 is coupled to the second metallic bar at a bottom end of the two-sided vapor chamber busbar 220 (e.g., an end opposite the terminal contact portion 228 of the two-sided vapor chamber busbar 220).

The two-sided vapor chamber busbar 220 can be a variety of shapes/sizes suitable for coupling to a terminal of PDU. Example shapes for the two-sided vapor chamber busbar 220 include a flat strip, a solid bar, and a rod. In some cases, the two-sided vapor chamber busbar 220 is curved, such that the terminal contact portion 228 is offset from an extending portion of the two-sided vapor chamber busbar 220. The first metallic bar 222 and the second metallic bar 226 can be formed of any suitable metal, including, but not limited to, copper, brass, and aluminum. In some cases, the shape of the vapor chamber 224 corresponds to the shape of the first metallic bar 222 and the second metallic bar 226.

FIG. 3A illustrates an example embodiment of a one-sided vapor chamber busbar. Referring to FIG. 3A, a one-sided vapor chamber busbar 300 can include similar components as the one-sided vapor chamber busbar 200 as described with respect to FIG. 2A. The one-sided vapor chamber busbar 300 includes a metallic bar 302 and a vapor chamber 304. The one-sided vapor chamber busbar 300 can include a terminal contact portion 308 that is offset from an extending portion of the one-sided vapor chamber busbar 300. The one-sided vapor chamber busbar 300 can include a plurality of holes 310 extending through the one-sided vapor chamber busbar 300 (e.g., including a plurality of holes formed in the vapor chamber 304 and a corresponding plurality of holes formed in the metallic bar 302).

FIG. 3B illustrates an example embodiment of a two-sided vapor chamber busbar. Referring to FIG. 3B, the two-sided vapor chamber busbar 320 can include similar components as the two-sided vapor chamber busbar 320 as described with respect to FIG. 3B. The two-sided vapor chamber busbar 320 includes a first metallic bar 322, a vapor chamber 324, and a second metallic bar 326. The two-sided vapor chamber busbar 320 can include a terminal contact portion 328 that is offset from an extending portion of the two-sided vapor chamber busbar 320.

The two-sided vapor chamber busbar 320 can include a plurality of holes 330 (e.g., including a plurality of holes formed in the vapor chamber 324, a corresponding plurality of holes formed in the first metallic bar 322, and a corresponding plurality of holes formed in the second metallic bar 326).

FIG. 3C illustrates an example embodiment of plurality of busbars coupled to a power distribution unit (PDU). Referring to FIG. 3C, the PDU 350 includes a first terminal 352, a second terminal 354, a first busbar 356, and a second busbar 358. Referring to FIGS. 3A-3C, the first busbar 356 and the second busbar 358 can be embodied as a one-sided vapor chamber busbar 300 or a two-sided vapor chamber busbar 320.

FIGS. 4A-4B illustrate example embodiments of a phase change material (PCM) busbar.

FIG. 4C illustrates an example PCM slab.

Referring to FIG. 4A, a PCM busbar 400 can include a first metallic bar 402 and a heat distribution block embodied as a phase change material (PCM) component 404. In some cases, the PCM component 404 is encapsulated by a metal block (i.e., metal slab). The first metallic bar 402 can include a first side 408a coupled to the PCM component 404 and a second side 408b configured to be coupled to a terminal of a PDU (e.g., first terminal 152, second terminal 154, third terminal 156, and fourth terminal 158 of PDU 150 as described with respect to FIG. 1, the first terminal 352 or the second terminal 354 as described with respect to FIG. 3C). The PCM busbar 400 can include a terminal contact portion 406 at the end of the PCM busbar 400 configured to be coupled to a terminal of a PDU. The PCM component 404 can be close to the terminal contact portion 406 of the PCM busbar 400. The PCM busbar 400 can include a hole 415 (e.g., including a hole formed in the PCM component 404 and a corresponding hole formed in the first metallic bar 402).

Referring to FIGS. 4B-4C, the PCM busbar 410 includes a metallic bar 420 and a PCM component 430. The PCM component 430 includes a PCM 434. In some cases, the PCM 434 is encapsulated by a metal slab 432 (i.e., metal block). In some cases, the metal slab 432 is a metal block containing the PCM 434. The PCM component 430 is coupled to a side of the metallic bar 420.

Example materials for forming the metal slab 432 can include, but are not limited to, aluminum, copper, silver, and a thermally conductive polymer.

In some cases, the PCM 434 of the PCM component 430 includes a plurality of holes 436 extending therethrough.

Example materials for the PCM 434 can include, but are not limited to, salt hydrates, fatty acids, esters, and various paraffins (e.g., octadecane). In some cases, a material for the PCM 434 is selected to have a melting temperature proximate to a “critical to quality” (CTQ) temperature of PDU terminal and high latent heat capacity.

The shape of the PCM component 430 can vary based on space constraints and the specifications of the particular PDU. In some cases, the shape of the PCM component 430 is selected to fit available space and to ensure effective heat absorption and dissipation at terminals.

Advantageously, when a PCM busbar 410 is coupled to a terminal of a PDU and a current spike occurs resulting in temperatures that reach a melting point of the PCM 434, a phase change process occurs which temporarily absorbs excess heat to reduce the temperature at the terminal.

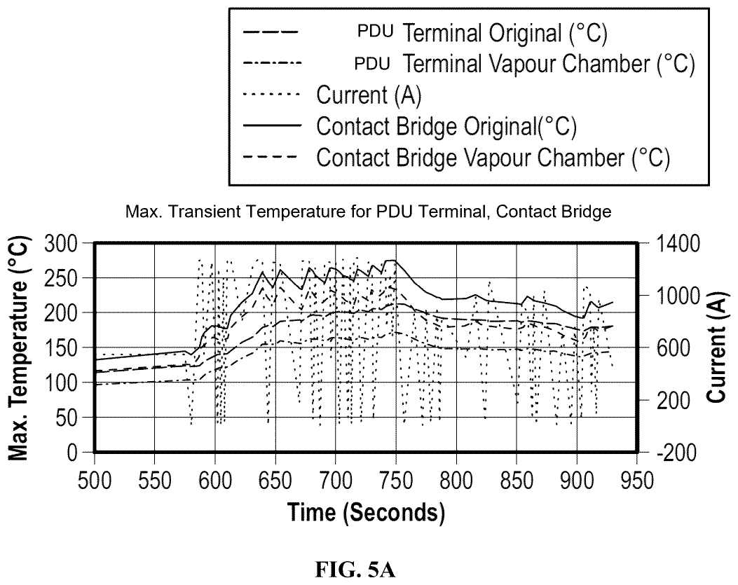

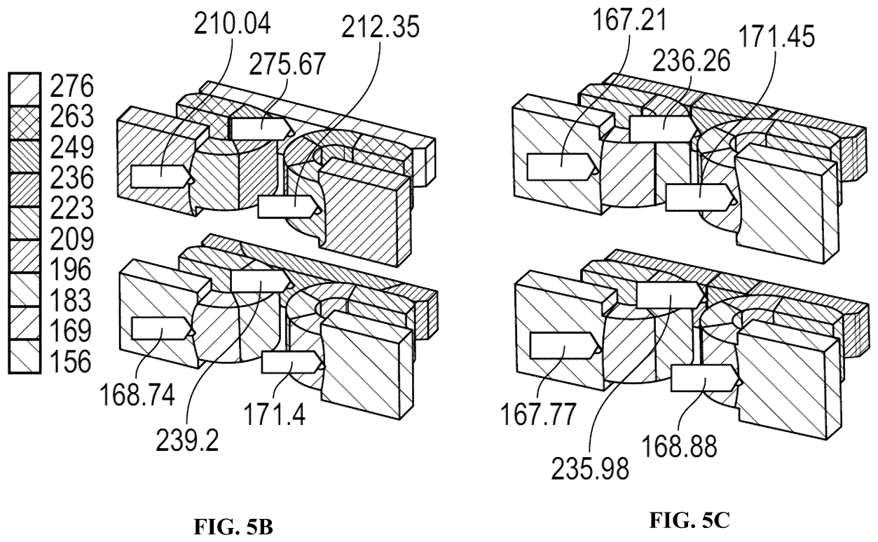

FIG. 5A illustrates a graph illustrating effects of vapor chamber busbar with one-sided architecture. Referring to FIG. 5A, the solid lines illustrate Reactor (e.g., PDU 150 as described with respect to FIG. 1 or PDU 350 as described with respect to FIG. 3C) terminal temperature when a conventional busbar is used and the dotted lines illustrate terminal temperature when a one-sided vapor chamber busbar is used.

FIG. 5B illustrates a temperature map of terminals of a PDU coupled by a contact bridge using a conventional busbar. FIG. 5C illustrates a temperature map of terminals of a PDU coupled by a contact bridge using a one-sided vapor chamber busbar.

Referring to FIGS. 5A-5C, as can be seen, the maximum temperature for the Reactor (e.g., PDU 150 as described with respect to FIG. 1 or PDU 350 as described with respect to FIG. 3C) can be reduced by approximately 40° C. by using a one-sided vapor chamber (e.g., one-sided vapor chamber busbar 200 as described with respect to FIG. 2A or one-sided vapor chamber busbar 300 as described with respect to FIG. 3A). Similar temperature reduction effects can be achieved using a two-sided vapor chamber (e.g., two-sided vapor chamber busbar 220 as described with respect to FIG. 2B or two-sided vapor chamber busbar 320 as described with respect to FIG. 3B) or a PCM busbar (e.g., PCM busbar 400 as described with respect to FIG. 4A and PCM busbar 410 as described with respect to FIG. 4B).

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A busbar for electrically connecting components in a power distribution unit (PDU), the busbar comprising:
a first metallic bar configured at one end to be coupled to a terminal of the PDU; and
a heat distribution block at the one end of the first metallic bar.

2. The busbar of claim 1, wherein the heat distribution block comprises a vapor chamber.

3. The busbar of claim 2, wherein a shape of the vapor chamber conforms to a shape of the one end.

4. The busbar of claim 3, wherein the one end is offset from an extending portion of the busbar.

5. The busbar of claim 2, further comprising a second metallic bar coupled to the first metallic bar with the vapor chamber there between.

6. The busbar of claim 5, wherein the second metallic bar contacts the first metallic bar toward an opposite end to the one end having the vapor chamber.

7. The busbar of claim 1, wherein the heat distribution block comprises a metal block, wherein the metal block comprises a phase change material.

8. The busbar of claim 7, wherein the phase change material is encapsulated within the metal block.

9. The busbar of claim 7, wherein the phase change material comprises a plurality of holes.

10. A power distribution unit (PDU), comprising:
a first terminal; and
a busbar, wherein the busbar comprises:
a first metallic bar having one end coupled to the first terminal of the PDU; and
a heat distribution block at the one end of the first metallic bar.

11. The PDU of claim 10, wherein the PDU comprises a battery disconnect unit.

12. The PDU of claim 10, wherein the heat distribution block comprises a vapor chamber.

13. The PDU of claim 12, wherein a shape of the vapor chamber conforms to a shape of the one end.

14. The PDU of claim 13, wherein the one end is offset from an extending portion of the busbar.

15. The PDU of claim 12, further comprising a second metallic bar coupled to the first metallic bar with the vapor chamber there between.

16. The PDU of claim 15, wherein the second metallic bar contacts the first metallic bar toward an opposite end to the one end having the vapor chamber.

17. The PDU of claim 10, wherein the heat distribution block comprises a metal block, wherein the metal block comprises a phase change material.

18. The PDU of claim 17, wherein the phase change material is encapsulated within the metal block.

19. The PDU of claim 17, wherein the phase change material comprises a plurality of apertures.
